(19) United States
(12) Patent Application Publication
(10) Pub. No.: US 2025/0183216 A1
(43) Pub. Date: Jun. 5, 2025

(54) SEMICONDUCTOR PACKAGE

(71) Applicant: Samsung Electronics Co., Ltd., Suwon-si (KR)

(72) Inventors: Sanghoon Lee, Suwon-si (KR); Yeongbeom Ko, Suwon-si (KR); Kyounglim Suk, Suwon-si (KR); Seokhyun LEE, Suwon-si (KR); Woojin Jang, Suwon-si (KR); Gwangjae Jeon, Suwon-si (KR)

(21) Appl. No.: 18/906,541

(22) Filed: Oct. 4, 2024

(30) Foreign Application Priority Data
Dec. 1, 2023 (KR) 10-2023-0172332

(51) Int. Cl. H01L 23/00; H01L 23/31; H01L 25/18; H10B 80/00

(52) U.S. Cl. CPC H01L 24/32; H01L 24/29; H01L 24/33; H01L 25/18; H01L 23/3107; H01L 2224/29147; H01L 2224/29187; H01L 2224/32145; H01L 2224/33181; H10B 80/00

(57) ABSTRACT

A semiconductor package includes a buffer die, first and second memory dies, first and second bonding layer structures, first and second molds, and an auxiliary substrate. The first memory dies are stacked on the buffer die. The first bonding layer structure is between the first memory dies, bonds the first memory dies together, and contains a first conductive bonding pattern structure. The first mold is on the buffer die, and covers sidewalls of the first memory dies and the first bonding layer structure. The second bonding layer structure is on the first memory dies and the first mold, and contains a second conductive bonding pattern structure. The second memory die is on the second bonding layer structure. The second mold is on the second bonding layer structure, and covers a sidewall of the second memory die. The auxiliary substrate is on the second memory die and the second mold.

### CROSS-REFERENCE TO RELATED APPLICATION

This application claims priority under 35 U.S.C. § 119 to Korean Patent Application No. 10-2023-0172332, filed on Dec. 1, 2023 in the Korean Intellectual Property Office (KIPO), the contents of which are herein incorporated by reference in their entirety.

### BACKGROUND

### 1. Field

Example embodiments relate to a semiconductor package. More particularly, example embodiments relate to a semiconductor package including a plurality of stacked chips.

### 2. Description of the Related Art

In a multi-chip package, a plurality of chips are stacked on a package substrate, and a bonding layer containing a conductive pattern is formed between the chips so that the chips may be electrically connected to each other. Thus, the characteristic of the bonding layer is important in the electrical connection between the chips.

### SUMMARY

Example embodiments provide a semiconductor package having enhanced electrical characteristics.

According to example embodiments, there is provided a semiconductor package. The semiconductor package may include a buffer die, first memory dies, a first bonding layer structure, a first mold, a second bonding layer structure, a second memory die, a second mold and an auxiliary substrate. The first memory dies may be sequentially stacked on the buffer die. The first bonding layer structure may be disposed between neighboring ones of the first memory dies, may bond the neighboring ones of the first memory dies with each other, and may contain a first conductive bonding pattern structure therein. The first mold may be disposed on the buffer die, and may cover sidewalls of the first memory dies and the first bonding layer structure. The second bonding layer structure may be disposed on the first memory dies and the first mold, and may contain a second conductive bonding pattern structure therein. The second memory die may be disposed on the second bonding layer structure. The second mold may be disposed on the second bonding layer structure, and may cover a sidewall of the second memory die. The auxiliary substrate may be disposed on the second memory die and the second mold.

According to example embodiments, there is provided a semiconductor package. The semiconductor package may include a buffer die, a first bonding layer structure, first memory dies, a second bonding layer structure, a third bonding layer structure, a second memory die and an auxiliary substrate. The first bonding layer structure may be disposed on the buffer die, may have a footprint substantially the same as the footprint of the buffer die, and may contain a first conductive bonding pattern structure therein. The first memory dies may be sequentially stacked on the first bonding layer structure, and each of the first memory dies may have a footprint smaller than the footprint of the buffer die. The second bonding layer structure may be disposed between neighboring ones of the first memory dies, may bond the neighboring ones of the first memory dies with each other, may have a footprint substantially the same as the footprint of each of the first memory dies, and may contain a second conductive bonding pattern structure therein. The third bonding layer structure may be disposed on an uppermost one of the first memory dies, may have a footprint substantially the same as the footprint of the buffer die, and may contain a third conductive bonding pattern structure therein. The second memory die may be disposed on the third bonding layer structure, and may have a footprint substantially the same as the footprint of each of the first memory dies. The auxiliary substrate may be disposed on the second memory die, and may have a footprint substantially the same as the footprint of the buffer die.

According to example embodiments, there is provided a semiconductor package. The semiconductor package may include a buffer die, a first bonding layer structure, first memory dies, a second bonding layer structure, a first mold, a third bonding layer structure, a second memory die, a second mold, a fourth bonding layer structure, an auxiliary substrate and a conductive connection member. The first bonding layer structure may be disposed on the buffer die, and may contain a first conductive bonding pattern structure therein. The first memory dies may be sequentially stacked on the first bonding layer structure. The second bonding layer structure may be disposed between neighboring ones of the first memory dies, may bond the neighboring ones of the first memory dies with each other, and may contain a second conductive bonding pattern structure therein. The first mold may be disposed on the first bonding layer structure, and may cover sidewalls of the first memory dies and the second bonding layer structure. The third bonding layer structure may be disposed on the first memory dies and the first mold, and may contain a third conductive bonding pattern structure therein. The second memory die may be disposed on the third bonding layer structure. The second mold may be disposed on the third bonding layer structure, and may cover a sidewall of the second memory die. The fourth bonding layer structure may be disposed on the second memory die and the second mold. The auxiliary substrate may be disposed on the fourth bonding layer structure. The conductive connection member may be electrically connected to the buffer die.

The semiconductor package in accordance with example embodiments may include a plurality of semiconductor chips that may be stacked in the vertical direction and bonded with each other by the bonding layer structure, no void may remain in the bonding layer structure. Thus, the semiconductor chips may be well bonded with each other, and the semiconductor package may have enhanced electrical characteristics.

### BRIEF DESCRIPTION OF THE DRAWINGS

FIG. 1 is a cross-sectional view illustrating a semiconductor package in accordance with example embodiments.

FIGS. 2 to 11 are cross-sectional views illustrating a method of manufacturing a semiconductor package in accordance with example embodiments.

FIGS. 12 to 19 are cross-sectional views illustrating semiconductor packages in accordance with example embodiments.

FIG. 20 is a cross-sectional view illustrating an electronic device in accordance with example embodiments.

### DETAILED DESCRIPTION OF EXAMPLE EMBODIMENTS

Hereinafter, example embodiments will be explained in detail with reference to the accompanying drawings. Hereinafter, a direction substantially parallel to an upper surface of a wafer or a substrate may be referred to as a horizontal direction, and a direction substantially perpendicular to the upper surface of the wafer or the substrate may be referred to as a vertical direction.

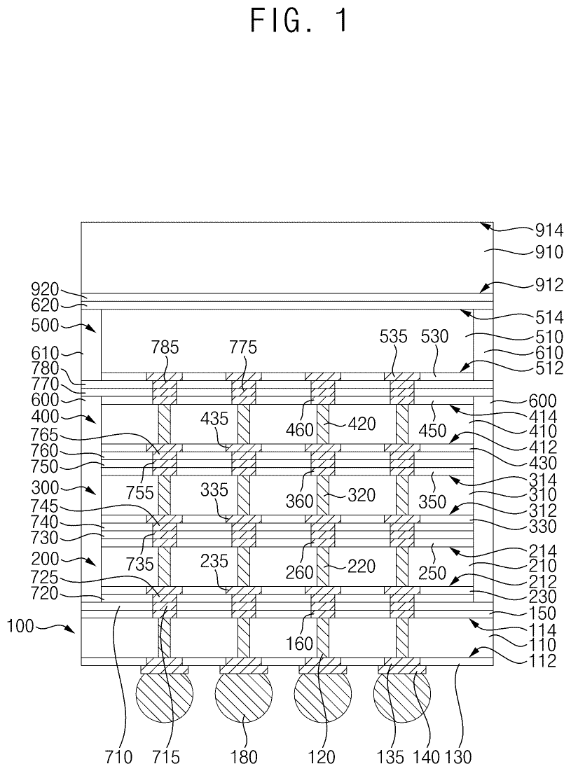

FIG. 1 is a cross-sectional view illustrating a semiconductor package in accordance with example embodiments.

Referring to FIG. 1, the semiconductor package may include a first semiconductor chip 100, second to fifth semiconductor chips 200, 300, 400 and 500 sequentially stacked on the first semiconductor chip 100, first to fourth bonding layer structures between neighboring ones of the first to fifth semiconductor chips 100, 200, 300, 400 and 500, first and second molds 600 and 610 on the first semiconductor chip 100 and covering sidewalls of the second to fifth semiconductor chips 200, 300, 400 and 500, an auxiliary substrate 910 on the fifth semiconductor chip 500 and the second mold 610, a fifth bonding layer structure between the auxiliary substrate 910 and the fifth semiconductor chip 500 and the second mold 610, and a first conductive connection member 180 under the first semiconductor chip 100.

In example embodiments, the first semiconductor chip 100 may be a buffer die, and may include a logic device, e.g., a controller, and each of the second to fifth semiconductor chips 200, 300, 400 and 500 may include a volatile memory device, e.g., DRAM device, SRAM device, etc., or a non-volatile memory device, e.g., flash memory device, EEPROM device, etc. For example, as a buffer die, the first semiconductor chip 100 may be configured to repeat signals comes from outside the semiconductor package to improve signal quality and/or signal strength to send the improved signals to the second to fifth semiconductor chips 200, 300, 400, and 500, and/or the first semiconductor chip 100 may be configured to repeat signals comes from the second to fifth semiconductor chips 200, 300, 400, and 500, to improve signal quality and/or signal strength to send the improved signals to the outside of the semiconductor package. For example, the second to fourth semiconductor chips 200, 300 and 400 may collectively form a middle core die, and the fifth semiconductor chip 500 may form a top core die.

FIG. 1 shows that the middle core die includes the second to fourth semiconductor chips 200, 300 and 400, however, the inventive concept is not limited thereto, and the middle core die may include a plurality of semiconductor chips. In example embodiments, the semiconductor package may be a high bandwidth memory (HBM) package.

The first semiconductor chip 100 may include a first substrate 110 having first and second surfaces 112 and 114 opposite to each other in the vertical direction, a first through electrode 120 extending lengthwise in the vertical direction through the first substrate 110, a first insulating interlayer and a second insulating interlayer 130 sequentially stacked in the vertical direction beneath the first surface 112 of the first substrate 110, a third insulating interlayer 150 on the second surface 114 of the first substrate 110, and an external connection pad 140 beneath the second insulating interlayer 130.

The first substrate 110 may include a semiconductor material, e.g., silicon, germanium, silicon-germanium, or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

A circuit device, e.g., a logic device may be formed beneath the first surface 112 of the first substrate 110. The circuit device may include circuit patterns, which may be covered by the first insulating interlayer.

The second insulating interlayer 130 may contain a first wiring structure 135 therein. For example, the second insulating interlayer 130 may surround and horizontally overlap the first wiring structure 135. The first wiring structure 135 may include, e.g., wirings, vias, contact plugs, etc., however, the first wiring structure 135 is shown as a single structure in FIG. 1 in order to avoid the complexity of the drawing.

The third insulating interlayer 150 may contain a first conductive pad 160 therein, and the first conductive pad 160 may extend, e.g., in the vertical direction, through the third insulating interlayer 150 to contact an upper surface of the first through electrode 120. For example, the third insulating interlayer 150 may surround and horizontally overlap the first conductive pad 160. It will be understood that when an element is referred to as being “attached,” “connected,” or “coupled” to or “on” another element, it can be directly attached, directly connected, or directly coupled to or on the other element or intervening elements may be present. In contrast, when an element is referred to as being “directly attached,” “directly connected,” or “directly coupled” to another element, or as “contacting” or “in contact with” another element, there are no intervening elements present at the point of contact.

The external connection pad 140 may be disposed under the second insulating interlayer 130, and may contact a portion of the first wiring structure 135 to be electrically connected thereto. As used herein, components described as being “electrically connected” are configured such that an electrical signal can be transferred from one component to the other (although such electrical signal may be attenuated in strength as it transferred and may be selectively transferred). In example embodiments, a plurality of external connection pads 140 may be spaced apart from each other in the horizontal direction.

The first through electrode 120 may extend, e.g., lengthwise, through the first substrate 110 in the vertical direction, and a plurality of first through electrodes 120 may be spaced apart from each other in the horizontal direction. The first through electrode 120 may have a shape of, e.g., a circle, an ellipse, a polygon, a polygon with rounded corners, etc., in a plan view.

In an example embodiment, the first through electrode 120 may extend, e.g., lengthwise in the vertical direction, through the first substrate 110 and the first insulating interlayer to contact the first conductive pad 160 and the first wiring structure 135, and may be electrically connected to the external connection pad 140 by the first wiring structure 135.

Alternatively, the first through electrode 120 may extend, e.g., lengthwise in the vertical direction, through the first substrate 110, the first insulating interlayer and the second insulating interlayer 130 to contact the first conductive pad 160 and the external connection pad 140, and may be electrically connected to the first conductive pad 160 and the external connection pad 140. Alternatively, the first through electrode 120 may extend, e.g., lengthwise in the vertical direction, through the first substrate 110 to contact the first conductive pad 160 and one of the circuit patterns included in the circuit device covered by the first insulating interlayer, and may be electrically connected to the external connection pad 140 by the one of the first circuit patterns and the first wiring structure 135.

The first conductive pad 160 and the external connection pad 140 may include or be formed of a metal, e.g., aluminum, copper, nickel, silver, etc., and the first insulating interlayer and the second and third insulating interlayers 130 and 150 may include or be formed of, e.g., silicon oxide or a low-k dielectric material such as an oxide doped with carbon or fluorine.

The first through electrode 120, and the wirings, the vias and the contact plugs included in the first wiring structure 135 may include or be formed of a conductive material, e.g., a metal, a metal nitride, a metal silicide, etc.

The second semiconductor chip 200 may include a second substrate 210 having first and second surfaces 212 and 214 opposite to each other in the vertical direction, a second through electrode 220 extending lengthwise in the vertical direction through the second substrate 210, a fourth insulating interlayer and a fifth insulating interlayer 230 sequentially stacked in the vertical direction beneath the first surface 212 of the second substrate 210, and a sixth insulating interlayer 250 on the second surface 214 of the second substrate 210.

The second substrate 210 may include or be formed of a semiconductor material, e.g., silicon, germanium, silicon-germanium, or a III-V group compound semiconductor, e.g., GaP, GaAs, GaSb, etc. In example embodiments, the second substrate 210 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be formed beneath the first surface 212 of the second substrate 210. The circuit device may include circuit patterns, which may be covered by the fourth insulating interlayer.

The fifth insulating interlayer 230 may contain a second wiring structure 235 therein. For example, the fifth insulating interlayer 230 may surround and horizontally overlap the second wiring structure 235. The second wiring structure 235 may include, e.g., wirings, vias, contact plugs, etc., however, the second wiring structure 235 is shown as a single structure in FIG. 1 in order to avoid the complexity of the drawing.

The sixth insulating interlayer 250 may contain a second conductive pad 260 therein, and the second conductive pad 260 may extend, e.g., in the vertical direction, through the sixth insulating interlayer 250 to contact an upper surface of the second through electrode 220. For example, the sixth insulating interlayer 250 may surround the second conductive pad 260.

The second through electrode 220 may extend, e.g., lengthwise, through the second substrate 210 in the vertical direction, and a plurality of second through electrodes 220 may be spaced apart from each other in the horizontal direction. The second through electrode 220 may have a shape of, e.g., a circle, an ellipse, a polygon, a polygon with rounded corners, etc., in a plan view.

In an example embodiment, the second through electrode 220 may extend, e.g., lengthwise in the vertical direction, through the second substrate 210 and the fourth insulating interlayer to contact the second conductive pad 260 and the second wiring structure 235. Alternatively, the second through electrode 220 may extend, e.g., lengthwise in the vertical direction, through the second substrate 210, the fourth insulating interlayer and the fifth insulating interlayer 230 to contact the second conductive pad 260. Alternatively, the second through electrode 220 may extend, e.g., lengthwise in the vertical direction, through the second substrate 210 to contact the second conductive pad 260 and one of the circuit patterns included in the circuit device covered by the fourth insulating interlayer, and may be electrically connected to the second wiring structure 235.

The second conductive pad 260 may include or be formed of a metal, e.g., aluminum, copper, nickel, silver, etc., and the fourth insulating interlayer and the fifth and sixth insulating interlayers 230 and 250 may include or be formed of, e.g., silicon oxide or a low-k dielectric material such as an oxide doped with carbon or fluorine.

The second through electrode 220, and the wirings, the vias and the contact plugs included in the second wiring structure 235 may include or be formed of a conductive material, e.g., a metal, a metal nitride, a metal silicide, etc.

The first bonding layer structure may bond the first and second semiconductor chips 100 and 200 with each other by a hybrid copper bonding (HCB) process, and may include first and second bonding layers 710 and 720 and first and second conductive bonding patterns 715 and 725 in the first and second bonding layers 710 and 720, respectively. For example, the first bonding layer structure may be formed of the first bonding layer 710, the second bonding layer 720, a plurality of first conductive bonding patterns 715, and a plurality of second conductive bonding patterns 725. In example embodiments, the first and second conductive bonding patterns 715 and 725 may contact each other to form a first conductive bonding pattern structure, and may contact the first conductive pad 160 and the second wiring structure 235.

In example embodiments, a planar area of the first bonding layer structure in the horizontal direction may be substantially the same as a planar area of the first semiconductor chip 100 in the horizontal direction. For example, the footprint or a plan view area of the first bonding layer structure may be substantially the same as the footprint or a plan view area of the first semiconductor chip 100. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

Each of the first and second bonding layers 710 and 720 may include or be formed of an insulating nitride, e.g., silicon carbonitride, silicon nitride, silicon oxynitride, etc., or an oxide, e.g., silicon oxide. Each of the first and second conductive bonding patterns 715 and 725 may include or be formed of a metal, e.g., copper, aluminum, etc.

The third to fifth semiconductor chips 300, 400 and 500 may be sequentially stacked in the vertical direction on the second semiconductor chip 200.

Each of the third to fifth semiconductor chips 300, 400 and 500 may have a structure substantially the same as or similar to that of the second semiconductor chip 200, and thus repeated explanations are omitted herein. A planar area of each of the third to fifth semiconductor chips 300, 400 and 500 in the horizontal direction may be substantially the same as a planar area of the second semiconductor chip 200 in the horizontal direction. For example, the footprint or a plan view area of each of the third to fifth semiconductor chips 300, 400 and 500 may be substantially the same as the footprint or a plan view area of the second semiconductor chip 200.

The third semiconductor chip 300 may include a third substrate 310 having first and second surfaces 312 and 314 opposite to each other in the vertical direction, a third through electrode 320 extending lengthwise in the vertical direction through the third substrate 310, a seventh insulating interlayer and an eighth insulating interlayer 330 sequentially stacked in the vertical direction beneath the first surface 312 of the third substrate 310, and a ninth insulating interlayer 350 on the second surface 314 of the third substrate 310.

The eighth insulating interlayer 330 may contain a third wiring structure 335 therein. For example, the eighth insulating interlayer 330 may surround and horizontally overlap the third wiring structure 335. The ninth insulating interlayer 350 may contain a third conductive pad 360 therein, and the third conductive pad 360 may extend through the ninth insulating interlayer 350, e.g., in the vertical direction, to contact an upper surface of the third through electrode 320. For example, the ninth insulating interlayer 350 may surround and horizontally overlap the third conductive pad 360. The third through electrode 320 may extend, e.g., lengthwise, through the third substrate 310 in the vertical direction, and a plurality of third through electrodes 320 may be spaced apart from each other in the horizontal direction. In an example embodiment, the third through electrode 320 may extend, e.g., lengthwise in the vertical direction, through the third substrate 310 and the seventh insulating interlayer to contact the third conductive pad 360 and the third wiring structure 335.

The fourth semiconductor chip 400 may include a fourth substrate 410 having first and second surfaces 412 and 414 opposite to each other in the vertical direction, a fourth through electrode 420 extending, e.g., lengthwise in the vertical direction, through the fourth substrate 410, a tenth insulating interlayer and an eleventh insulating interlayer 430 sequentially stacked in the vertical direction beneath the first surface 412 of the fourth substrate 410, and a twelfth insulating interlayer 450 on the second surface 414 of the fourth substrate 410.

The eleventh insulating interlayer 430 may contain a fourth wiring structure 435 therein. For example, the eleventh insulating interlayer 430 may surround and horizontally overlap fourth wiring structure 435. The twelfth insulating interlayer 450 may contain a fourth conductive pad 460 therein, and the fourth conductive pad 460 may extend, e.g., in the vertical direction, through the twelfth insulating interlayer 450 to contact an upper surface of the fourth through electrode 420. For example, the twelfth insulating interlayer 450 may surround and horizontally overlap the fourth conductive pad 460. The fourth through electrode 420 may extend, e.g., lengthwise, through the fourth substrate 410 in the vertical direction, and a plurality of fourth through electrodes 420 may be spaced apart from each other in the horizontal direction. In an example embodiment, the fourth through electrode 420 may extend, e.g., lengthwise in the vertical direction, through the fourth substrate 310 and the tenth insulating interlayer to contact the fourth conductive pad 460 and the fourth wiring structure 435.

The fifth semiconductor chip 500 may include a fifth substrate 510 having first and second surfaces 512 and 514 opposite to each other in the vertical direction, and a thirteenth insulating interlayer and a fourteenth insulating interlayer 530 sequentially stacked in the vertical direction beneath the first surface 512 of the fifth substrate 510. The fourteenth insulating interlayer 530 may contain a fifth wiring structure 535 therein. For example, the fourteenth insulating interlayer 530 may surround and horizontally overlap the fifth wiring structure 535.

In an example embodiment, a thickness in the vertical direction of the fifth substrate 510 included in the fifth semiconductor chip 500 may be equal to or less than about 100 um. In example embodiments, a planar area of the fifth semiconductor chip 500 in the horizontal direction may be substantially the same as that of each of the second to fourth semiconductor chips 200, 300 and 400. For example, the footprint or a plan view area of the fifth semiconductor chip 500 may be substantially the same as the footprint or a plan view area of each of the second to fourth semiconductor chips 200, 300 and 400.

Each of the third to fifth substrates 310, 410 and 510 may include or be formed of a semiconductor material, e.g., silicon, germanium, silicon-germanium, or a III-V group compound semiconductor, e.g., GaP, GaAs, GaSb, etc. In example embodiments, each of the third to fifth substrates 310, 410 and 510 may be a silicon-on-insulator (SOI) substrate or a germanium-on-insulator (GOI) substrate.

A circuit device such as a volatile memory device, e.g., DRAM device, SRAM device, etc., or a non-volatile memory device, e.g., flash memory device, EEPROM device, etc. may be formed beneath each of the first surfaces 312, 412 and 512 of the third to fifth substrates 310, 410 and 510. The circuit device may include circuit patterns, which may be covered by the seventh, tenth and thirteenth insulating interlayers.

Like the first bonding layer structure that may bond the first and second semiconductor chips 100 and 200 with each other by an HCB process, the second to fourth bonding layer structures may bond the second to fifth semiconductor chips 200, 300, 400 and 500 together by an HCB process.

For example, the second bonding layer structure may include third and fourth bonding layers 730 and 740 and third and fourth conductive bonding patterns 735 and 745 in the third and fourth bonding layers 730 and 740, respectively. For example, the second bonding layer structure may be formed of the third bonding layer 730, the fourth bonding layer 740, a plurality of third conductive bonding patterns 735, and a plurality of fourth conductive bonding patterns 745. In example embodiments, the third and fourth conductive bonding patterns 735 and 745 may contact each other to form a second conductive bonding pattern structure, and may contact the second conductive pad 260 and the third wiring structure 335.

The third bonding layer structure may include fifth and sixth bonding layers 750 and 760 and fifth and sixth conductive bonding patterns 755 and 765 in the fifth and sixth bonding layers 750 and 760, respectively. For example, the third bonding layer structure may be formed of the fifth bonding layer 750, the sixth bonding layer 760, a plurality of fifth conductive bonding patterns 755, and a plurality of sixth conductive bonding patterns 765. In example embodiments, the fifth and sixth conductive bonding patterns 755 and 765 may contact each other to form a third conductive bonding pattern structure, and may contact the third conductive pad 360 and the fourth wiring structure 435.

In example embodiments, a planar area of each of the second and third bonding layer structures in the horizontal direction may be substantially the same as a planar area of each of the second to fourth semiconductor chips 200, 300 and 400 in the horizontal direction. For example, the footprint or a plan view area of each of the second and third bonding layer structures may be substantially the same as the footprint or a plan view area of each of the second to fourth semiconductor chips 200, 300 and 400.

Additionally, the fourth bonding layer structure may include seventh and eighth bonding layers 770 and 780 and seventh and eighth conductive bonding patterns 775 and 785 in the seventh and eighth bonding layers 770 and 780, respectively. For example, the fourth bonding layer structure may be formed of the seventh bonding layer 770, the eighth bonding layer 780, a plurality seventh conductive bonding patterns 775, and a plurality eighth conductive bonding patterns 785. In example embodiments, the seventh and eighth conductive bonding patterns 775 and 785 may contact each other to form a fourth conductive bonding pattern structure, and may contact the fourth conductive pad 460 and the fifth wiring structure 535.

In example embodiments, a planar area of the fourth bonding layer structure in the horizontal direction may be substantially the same as the planar area of the first bonding layer structure in the horizontal direction. For example, the footprint or a plan view area of the fourth bonding layer structure may be substantially the same as the footprint or the plan view area of the first bonding layer structure.

The first to fifth semiconductor chips 100, 200, 300, 400 and 500 may be electrically connected to each other by the first to fourth through electrodes 120, 220, 320 and 420 extending through the first to fourth substrates 110, 210, 310 and 410, respectively, the first to fourth conductive pads 160, 260, 360 and 460 and the first to fifth wiring structures 135, 235, 335, 435 and 535 electrically connected to the first to fourth through electrodes 120, 220, 320 and 420, and the first to eighth conductive bonding patterns 715, 725, 735, 745, 755, 765, 775 and 785 included in the first to fourth bonding layer structures that may bond the first to fifth semiconductor chips 100, 200, 300, 400 and 500 with each other, and electrical signals, e.g., data signals, control signals, etc., may be transferred to each other.

The first mold 600 may cover/contact sidewalls of the second to fourth semiconductor chips 200, 300 and 400 on the first semiconductor chip 100, and an upper surface of the first mold 600 may be substantially coplanar with an upper surface of the fourth semiconductor chip 400. The seventh and eighth bonding layers 770 and 780 included in the fourth bonding layer structure may be formed on the fourth semiconductor chip 400 and the first mold 600. For example, the fourth bonding layer structure and/or the seventh bonding layer 770 may contact a top surface of the first mold 600.

The second mold 610 may be formed on the fourth bonding layer structure, and may cover the fifth semiconductor chip 500. For example, the second mold 610 may cover and contact sidewalls of the fifth semiconductor chip 500. An upper surface of the second mold 610 may be substantially coplanar with an upper surface of the fifth semiconductor chip 500.

In example embodiments, each of the first and second molds 600 and 610 may include or be formed of an oxide, e.g., silicon oxide, or an organic insulating material.

The ninth and tenth bonding layers 620 and 920 included in the fifth bonding layer structure may be formed on the fifth semiconductor chip 500 and the second mold 610. For example, the fifth bonding layer structure may be formed of the ninth bonding layer 620 and the tenth bonding layer 920. In example embodiments, a planar area of the fifth bonding layer structure in the horizontal direction may be substantially the same as the planar area of the first bonding layer structure in the horizontal direction. For example, the footprint or a plan view area of the fifth bonding layer structure may be substantially the same as the footprint or the plan view area of the first bonding layer structure.

The auxiliary substrate 910 may be formed on the fifth bonding layer structure, and may be bonded with the fifth substrate 510 of the fifth semiconductor chip 500 through the fifth bonding layer structure.

The auxiliary substrate 910 may include or be formed of a semiconductor material, e.g., silicon, germanium, silicon-germanium, or a III-V group compound semiconductor, e.g., GaP, GaAs, GaSb, etc. Alternatively, the auxiliary substrate 910 may include or be formed of glass.

The first conductive connection member 180 may contact a lower surface of the external connection pad 140 of the first semiconductor chip 100. The first conductive connection member 180 may be a conductive bump including, e.g., solder. For example, the first conductive connection member 180 may be a solder ball or a solder bump.

In example embodiments, the second to fourth substrates 210, 310 and 410 of the second to fourth semiconductor chips 200, 300 and 400 may have substantially the same thickness in the vertical direction, and the fifth substrate 510 of the fifth semiconductor chip 500 may be substantially the same as or slightly greater than that of each of the second to fourth substrates 210, 310 and 410.

The auxiliary substrate 910 may be additionally formed on the fifth semiconductor chip 500, and may be bonded with the fifth semiconductor chip 500 by the fifth bonding layer structure, which may collectively form a top core die. Thus, even though the fifth semiconductor chip 500 serving as an active chip has a small thickness in the vertical direction, the top core die may satisfy a required thickness in the semiconductor package.

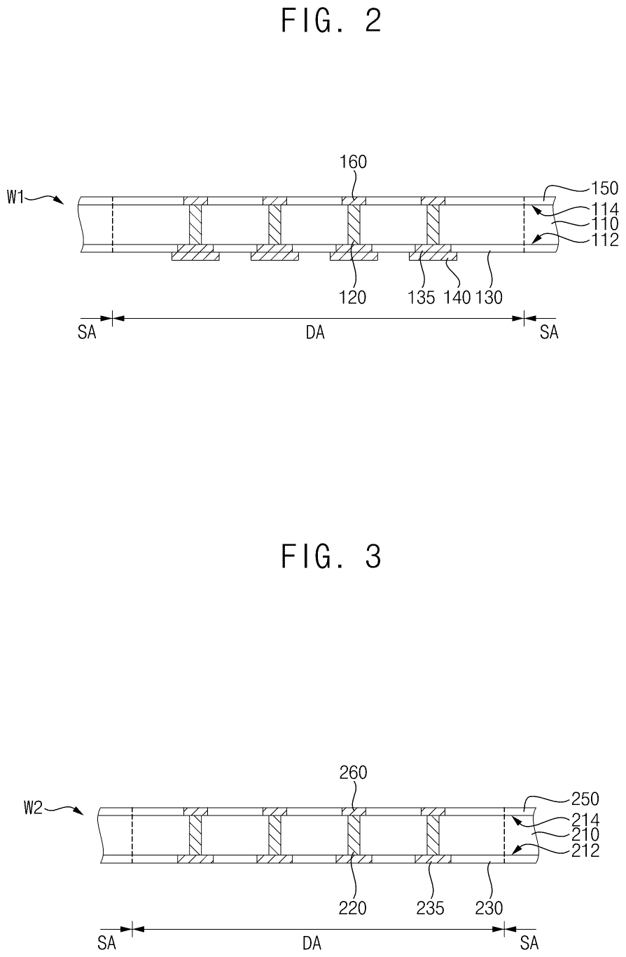

As illustrated below with reference to FIGS. 2 to 11, as the fifth semiconductor chip 500 has the thickness substantially the same as or slightly greater than that of each of the second to fourth substrates 210, 310 and 410, no void may be generated in the fourth bonding layer structure, and thus the semiconductor package may have enhanced electrical characteristics.

FIGS. 2 to 11 are cross-sectional views illustrating a method of manufacturing a semiconductor package in accordance with example embodiments.

Referring to FIG. 2, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into a plurality of first semiconductor chips.

In each die region DA, a circuit device may be formed beneath the first surface 112 of the first substrate 110. The circuit device may include a logic device. The circuit device may include circuit patterns, and a first insulating interlayer may be formed beneath the first surface 112 of the first substrate 110 to cover the circuit patterns.

A second insulating interlayer 130 may be formed beneath the first insulating interlayer, and may contain a first wiring structure 135 therein. For example, the second insulating interlayer 130 may surround and horizontally overlap the first wiring structure 135. The first wiring structure 135 may include, e.g., wirings, vias, contact plugs, etc., however, the first wiring structure 135 is shown as a single structure in FIG. 2 in order to avoid the complexity of the drawing.

An external connection pad 140 may be formed under the second insulating interlayer 130, and may contact a portion of the first wiring structure 135 to be electrically connected thereto.

A first through electrode 120 may be formed to extend through the first substrate 110 in the vertical direction. In example embodiments, a plurality of first through electrodes 120 may be spaced apart from each other in the horizontal direction.

A first conductive pad 160 may be formed on the second surface 114 of the first substrate 110 to contact an upper surface of the first through electrode 120. A plurality of first conductive pads 160 may be spaced apart from each other in the horizontal direction according to the layout of the first through electrode 120. A third insulating interlayer 150 may be formed on the second surface 114 of the first substrate 110 to cover/contact a sidewall of the first conductive pad 160.

Referring to FIG. 3, a second wafer W2 may be provided.

In example embodiments, the second wafer W2 may include a second substrate 210 having first and second surfaces 212 and 214 opposite to each other in the vertical direction. Additionally, the second wafer W2 may include a plurality of die regions DA and a scribe lane region SA surrounding each of the die regions DA. The second wafer W2 may be cut along the scribe lane region SA by a sawing process to be singulated into a plurality of second semiconductor chips.

In the die region DA, a circuit device may be formed beneath the first surface 212 of the second substrate 210. The circuit device may include a memory device. The circuit device may include circuit patterns, and a fourth insulating interlayer may be formed beneath the first surface 212 of the second substrate 210 to cover the circuit patterns.

A fifth insulating interlayer 230 may be formed beneath the fourth insulating interlayer, and may contain a second wiring structure 235 therein. For example, the fifth insulating interlayer 230 may surround and horizontally overlap the second wiring structure 235. The second wiring structure 235 may include, e.g., wirings, vias, contact plugs, etc., however, the second wiring structure 235 is shown as a single structure in FIG. 2 in order to avoid the complexity of the drawing.

A second through electrode 220 may be formed to extend through the second substrate 210 in the vertical direction. In example embodiments, a plurality of second through electrodes 220 may be spaced apart from each other in the horizontal direction.

A second conductive pad 260 may be formed on the second surface 214 of the second substrate 210 to contact an upper surface of the second through electrode 220. A plurality of second conductive pads 260 may be spaced apart from each other in the horizontal direction according to the layout of the second through electrode 220. A sixth insulating interlayer 250 may be formed on the second surface 214 of the second substrate 210 to cover/contact a sidewall of the second conductive pad 260.

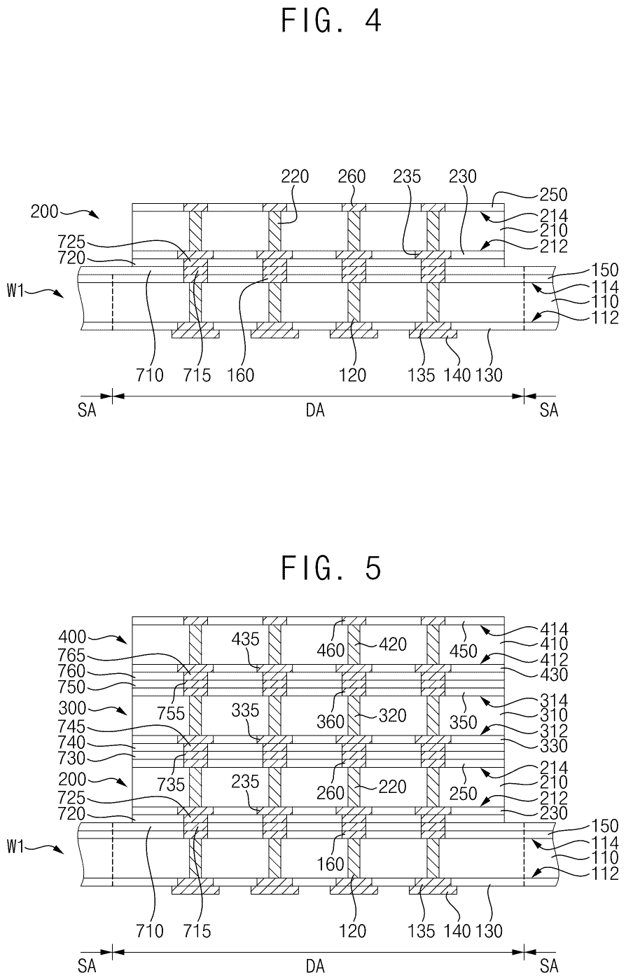

Referring to FIG. 4, the first wafer W1 and the second semiconductor chips may be bonded with each other by a hybrid copper bonding (HCB) process, as follows.

For example, a first bonding layer 710 containing/surrounding a first conductive bonding pattern 715 may be formed on the third insulating interlayer 150 and the first conductive pad 160 of the first wafer W1.

In example embodiments, a plurality of first conductive bonding patterns 715 may be spaced apart from each other in the horizontal direction, and each of the first conductive bonding patterns 715 may contact a corresponding one of the first conductive pads 160.

After cutting the wafer W2 along the scribe lane region SA by a sawing process into second semiconductor chips 200, a second bonding layer 720 containing/surrounding a second conductive bonding pattern 725 may be formed on the fifth insulating interlayer 230 and the second wiring structure 235 of each of the second semiconductor chips 200.

In example embodiments, a plurality of second conductive bonding patterns 725 may be spaced apart from each other in the horizontal direction, and each of the second conductive bonding patterns 725 may contact a portion of the second wiring structure 235.

In some embodiments, the second bonding layer 720 may be formed on the fifth insulating interlayer 230 and the second wiring structure 235 of the second wafer W2, before the sawing process.

Each of the second semiconductor chips 200 may be mounted on the first wafer W1 such that the second bonding layer 720 on each of the semiconductor chips 200 may contact the first bonding layer 710 on the first wafer W1, and each of the second semiconductor chips 200 may be pressed onto the first wafer W1 so that lower surfaces of the second conductive bonding patterns 725 may contact upper surfaces of the first conductive bonding patterns 715, respectively.

A thickness of the second semiconductor chip 200 in the vertical direction may be small, and thus when the second semiconductor chip 200 is pressed, the second semiconductor chip 200 may be partially transformed so that void between the first and second bonding layers 710 and 720 may be emitted out of the second semiconductor chip 200, e.g., in a plan view. For example, void or bubbles may be removed from between the first and second bonding layers 710 and 720 by the pressing process. For example, the void or the bubbles may be filled with gas or air. Thus, no void may remain between the first and second bonding layers 710 and 720, and the first and second bonding layers 710 and 720 may be well bonded with each other.

The first and second bonding layers 710 and 720 stacked in the vertical direction and bonded with each other may collectively form a first bonding layer structure, and the first and second bonding patterns 715 and 725 stacked in the vertical direction and bonded with each other may collectively form a first conductive bonding pattern structure.

In example embodiments, the second semiconductor chips 200 may be disposed on the first wafer W1 so as to correspond to the die regions DA of the first wafer W1, and the second through electrodes 220 in each of the second semiconductor chips 200 may overlap corresponding ones of the first through electrodes 120, respectively, in the vertical direction.

Referring to FIG. 5, third and fourth semiconductor chips 300 and 400 may be sequentially stacked on the second semiconductor chip 200, and the second to fourth semiconductor chips 200, 300 and 400 may be bonded with each other by an HCB process, as follows.

A third bonding layer 730 containing/surrounding a third conductive bonding pattern 735 may be formed on the sixth insulating interlayer 250 and the second conductive pad 260 of the second semiconductor chip 200.

Processes substantially the same as or similar to those illustrated with respect to FIG. 4 may be performed to form a plurality of third semiconductor chips 300, and a fourth bonding layer 740 containing/surrounding a fourth conductive bonding pattern 745 may be formed on an eighth insulating interlayer 330 and a third wiring structure 335 of each of the third semiconductor chips 300.

The third semiconductor chips 300 may be mounted on corresponding ones of the second semiconductor chips 200, respectively, such that the fourth bonding layer 740 on each of the third semiconductor chips 300 may contact the third bonding layer 730 on the corresponding one of the second semiconductor chips 200, and each of the third semiconductor chips 300 may be pressed onto the corresponding one of the second semiconductor chips 200 so that lower surfaces of the fourth conductive bonding patterns 745 may contact upper surfaces of the third conductive bonding patterns 735, respectively.

A thickness of the third semiconductor chip 300 in the vertical direction may be small, and thus when the third semiconductor chip 300 is pressed, the third semiconductor chip 300 may be partially transformed so that void between the third and fourth bonding layers 730 and 740 may be emitted out of the third semiconductor chip 300, e.g., in a plan view. For example, void or bubbles formed between the third and fourth bonding layers 730 and 740 may be removed from between the third and fourth bonding layers 730 and 740 by the pressing process. For example, the void or the bubbles may be filled with gas or air. Thus, no void may remain between the third and fourth bonding layers 730 and 740, and the third and fourth bonding layers 730 and 740 may be well bonded with each other.

The third and fourth bonding layers 730 and 740 stacked in the vertical direction and bonded with each other may collectively form a second bonding layer structure, and the third and fourth bonding patterns 735 and 745 stacked in the vertical direction and bonded with each other may collectively form a second conductive bonding pattern structure.

In example embodiments, each third through electrode 320 of the third semiconductor chips 300 may overlap a corresponding one of the second through electrodes 220 of the second semiconductor chips 200 in the vertical direction.

A fifth bonding layer 750 containing/surrounding a fifth conductive bonding pattern 755 may be formed on a ninth insulating interlayer 350 and a third conductive pad 360 in the third semiconductor chip 300.

Processes substantially the same as or similar to those illustrated with respect to FIG. 4 may be performed to form a plurality of fourth semiconductor chips 400, and a sixth bonding layer 760 containing/surrounding a sixth conductive bonding pattern 765 may be formed on an eleventh insulating interlayer 430 and a fourth wiring structure 435 of each of the fourth semiconductor chips 400.

The fourth semiconductor chips 400 may be mounted on corresponding ones of the third semiconductor chips 300, respectively, such that the sixth bonding layer 760 on each of the fourth semiconductor chips 400 may contact the fifth bonding layer 750 on the corresponding one of the third semiconductor chips 300, and each of the fourth semiconductor chips 400 may be pressed onto the corresponding one of the third semiconductor chips 300 so that lower surfaces of the sixth conductive bonding patterns 765 may contact upper surfaces of the fifth conductive bonding patterns 755, respectively.

A thickness of the fourth semiconductor chip 400 in the vertical direction may be small, and thus when the fourth semiconductor chip 400 is pressed, the fourth semiconductor chip 400 may be partially transformed so that void between the fifth and sixth bonding layers 750 and 760 may be emitted out of the fourth semiconductor chip 400, e.g., in a plan view. For example, void or bubbles formed between the fifth and sixth bonding layers 750 and 760 may be removed from between the fifth and sixth bonding layers 750 and 760 by the pressing process. For example, the void or the bubbles may be filled with gas or air. Thus, no void may remain between the fifth and sixth bonding layers 750 and 760, and the fifth and sixth bonding layers 750 and 760 may be well bonded with each other.

The fifth and sixth bonding layers 750 and 760 stacked in the vertical direction and bonded with each other may collectively form a third bonding layer structure, and the fifth and sixth bonding patterns 755 and 765 stacked in the vertical direction and bonded with each other may collectively form a third conductive bonding pattern structure.

In example embodiments, each fourth through electrode 420 of the fourth semiconductor chips 400 may overlap a corresponding third through electrode 320 of the third semiconductor chips 300 in the vertical direction.

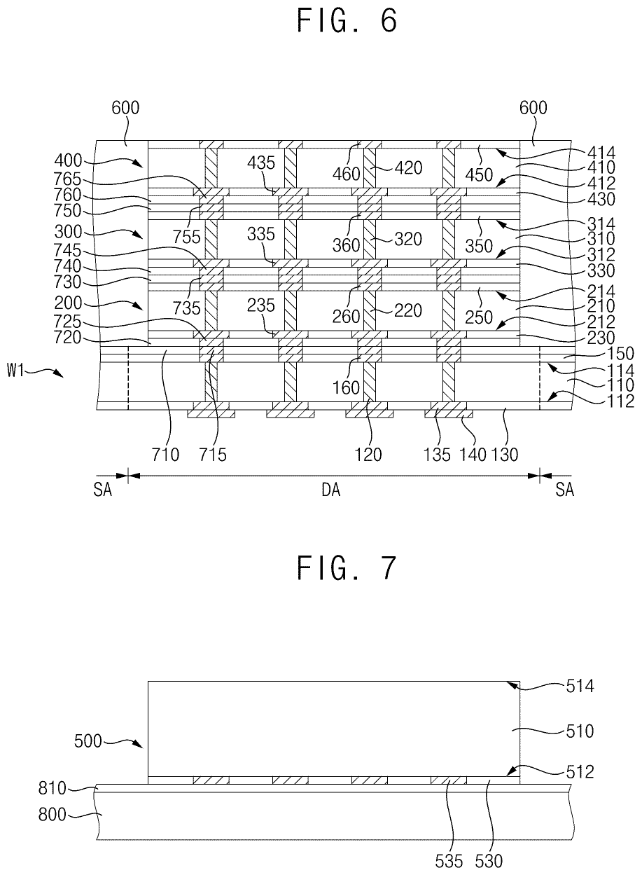

Referring to FIG. 6, a first mold 600 may be formed on the first wafer W1 to fill a space between structures each of which may include the second to fourth semiconductor chips 200, 300 and 400.

In example embodiments, the first mold 600 may expose an upper surface of the fourth semiconductor chip 400. The first mold 600 may include or be formed of an oxide, e.g., silicon oxide.

Referring to FIG. 7, processes substantially the same as or similar to those illustrated with respect to FIG. 4 may be performed to form a plurality of fifth semiconductor chips 500, and each of the fifth semiconductor chips 500 may be mounted on a carrier substrate 800.

In example embodiments, a temporary bonding layer 810 may be attached to the carrier substrate 800, and the fifth semiconductor chip 500 and the carrier substrate 800 may be bonded with each other such that a fourteenth insulating interlayer 530 and a fifth wiring structure 535 of the fifth semiconductor chip 500 face an upper surface of the temporary bonding layer 810.

The temporary bonding layer 810 may include a material that may lose adhesion (e.g., adhesive force) by an irradiation of light or heating. In an example embodiment, the temporary bonding layer 810 may include or may be a release tape.

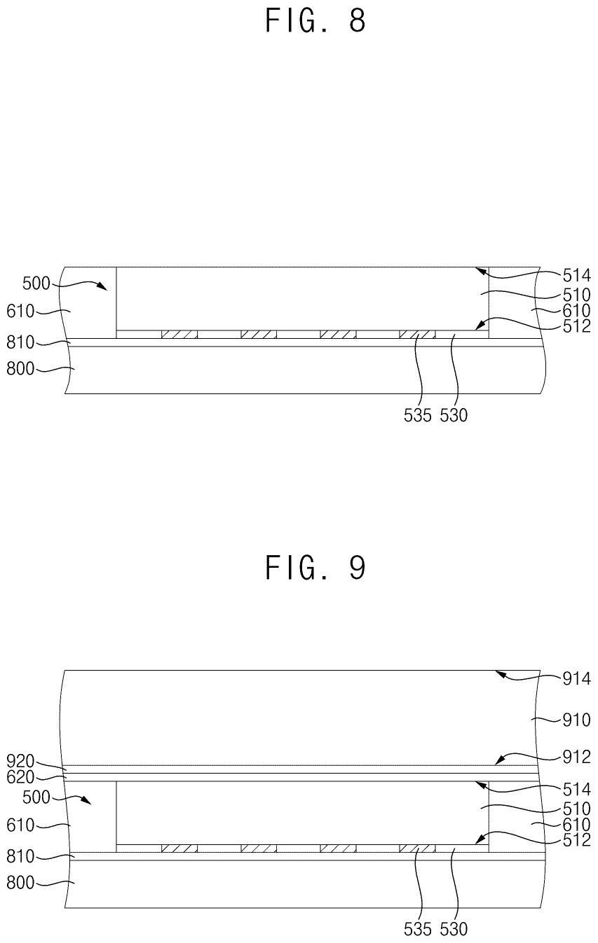

Referring to FIG. 8, a portion of the fifth semiconductor chip 500 adjacent to the second surface 514 (e.g., an upper portion) of the fifth substrate 510 may be removed by, e.g., a grinding process, so that a thickness of the fifth semiconductor chip 500 in the vertical direction may be reduced.

In example embodiments, the thickness of the fifth semiconductor chip 500 after the grinding process may be substantially the same as or slightly greater than that of each of the second to fourth semiconductor chips 200, 300 and 400. In an example embodiment, the thickness of the fifth semiconductor chip 510 may be equal to or less than about 100 um.

A second mold layer may be formed on the temporary bonding layer 810 to cover the fifth semiconductor chip 500, and a planarization process may be performed on the second mold layer until an upper surface of the fifth semiconductor chip 500 is exposed, and thus a second mold 610 covering/contacting a sidewall of the fifth semiconductor chip 500 may be formed. In example embodiments, the planarization process may include or may be a chemical mechanical polishing (CMP) process. The thickness of the fifth semiconductor chip 500 has been reduced by the grinding process, and thus the planarization process on the second mold layer covering the fifth semiconductor chip 500 may be efficiently performed in a short time.

The second mold 610 may include or be formed of an oxide, e.g., silicon oxide.

Referring to FIG. 9, an auxiliary substrate 910 may be bonded with the fifth semiconductor chip 500 and the second mold 610 on the carrier substrate 800.

In example embodiments, a ninth bonding layer 620 may be formed on the fifth semiconductor chip 500 and the second mold 610, a tenth bonding layer 920 may be formed on a first surface 912 of the auxiliary substrate 910, and a plasma treatment may be performed on the ninth and tenth bonding layers 620 and 920. The ninth and tenth bonding layers 620 and 920 stacked in the vertical direction and bonded with each other may collectively form a fifth bonding layer structure.

Each of the ninth and tenth bonding layers 620 and 920 may include or be formed of an oxide, e.g., silicon oxide.

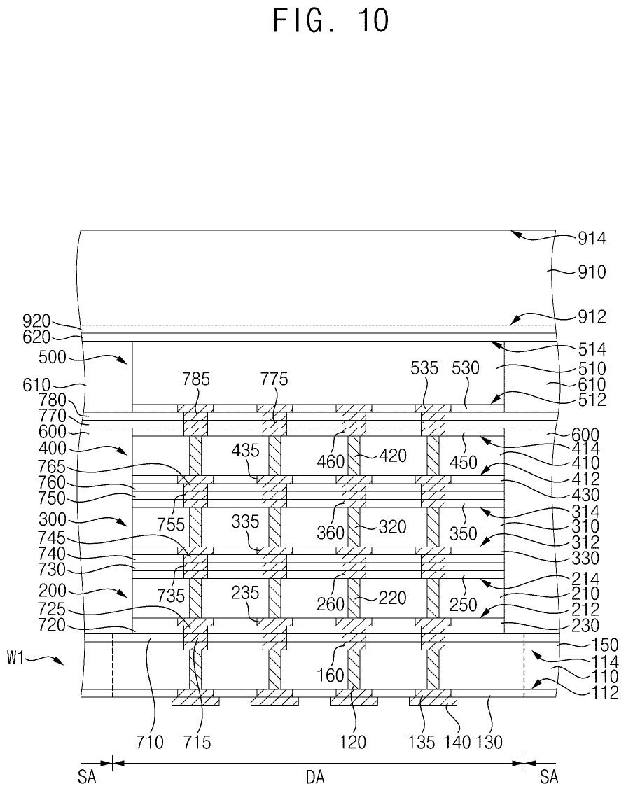

Referring to FIG. 10, the temporary bonding layer 810 on the carrier substrate 800 may be separated from the fourteenth insulating interlayer 530 and the fifth wiring structure 535 so that the carrier substrate 800 may be separated from the fifth semiconductor chip 500, and thus the fourteenth insulating interlayer 530 and the fifth wiring structure 535 may be exposed.

The auxiliary substrate 910 and the fifth semiconductor chip 500 may be bonded with the first wafer W1 having the second to fourth semiconductor chips 200, 300 and 400 and the first mold 600 thereon by an HCB process, as follows.

For example, a seventh bonding layer 770 containing/surrounding a seventh conductive bonding pattern 775 may be formed on a twelfth insulating interlayer 450 and a fourth conductive pad 460 of the fourth semiconductor chip 400.

In example embodiments, a plurality of seventh conductive bonding patterns 775 may be spaced apart from each other in the horizontal direction, and the seventh conductive bonding patterns 775 may contact corresponding ones of the fourth conductive pads 460, respectively.

An eighth bonding layer 780 containing/surrounding an eighth conductive bonding pattern 785 may be formed on a fourteenth insulating interlayer 530 and a fifth wiring structure 535 of the fifth semiconductor chip 500 and the second mold 610.

In example embodiments, a plurality of eighth conductive bonding patterns 785 may be spaced apart from each other in the horizontal direction, and the eighth conductive bonding patterns 785 may contact corresponding ones of the fifth wiring structures 535, respectively.

The fifth semiconductor chips 500 may be mounted on corresponding ones of the fourth semiconductor chips 400, respectively, such that the eighth bonding layer 780 of each of the fifth semiconductor chips 500 may contact the seventh bonding layer 770 of a corresponding one of the fourth semiconductor chips 400, and the auxiliary substrate 910 may be pressed onto the fourth semiconductor chip 400 so that lower surfaces of the eighth conductive bonding patterns 785 may contact upper surfaces of the seventh conductive bonding patterns 775, respectively.

A total thickness in the vertical direction of the fifth semiconductor chip 500 and the auxiliary substrate 910 bonded thereto may be greater than a thickness in the vertical direction of each of the second to fourth semiconductor chips 200, 300 and 400. However, unlike when each of the second to fourth semiconductor chips 200, 300 and 400 is pressed, a plurality of fifth semiconductor chips 500 are bonded with the auxiliary substrate 910, and thus the pressure may be performed not by the unit of a chip, but by the unit of a wafer.

Thus, a thickness in the vertical direction of the auxiliary substrate 910 and the fifth semiconductor chip 500 is relatively thin comparing with a planar area (a plan view area or the footprint) of the wafer or the auxiliary substrate 910 so that the auxiliary substrate 910 and the fifth semiconductor chip 500 may be easily transformed during the pressure, and thus void that may be generated between the seventh and eighth bonding layers 770 and 780 may be emitted out of the fifth semiconductor chip 500, e.g., in a plan view. For example, void or bubbles formed between the seventh and eighth bonding layers 770 and 780 may be removed from between the seventh and eighth bonding layers 770 and 780 by the pressing process. For example, the void or the bubbles may be filled with gas or air. Accordingly, no void may remain between the seventh and eighth bonding layers 770 and 780, and the seventh and eighth bonding layers 770 and 780 may be well bonded with each other.

The seventh and eighth bonding layers 770 and 780 stacked in the vertical direction and bonded with each other may collectively form a fourth bonding layer structure, and the seventh and eighth conductive bonding patterns 775 and 785 stacked in the vertical direction and bonded with each other may collectively form a fourth conductive bonding pattern structure.

Referring to FIG. 11, a portion of the auxiliary substrate 910 adjacent to a second surface 914 (e.g., an upper portion) of the auxiliary substrate 910 may be removed by, e.g., a grinding process, so that a thickness in the vertical direction of the auxiliary substrate 910 may be reduced.

The first wafer W1 may be cut along the scribe lane region SA by, e.g., a sawing process to be singulated into a plurality of first semiconductor chips 100, e.g., on which above mentioned structures attached as shown in FIG. 11.

During the sawing process, the first and second molds 600 and 610 may also be cut, and may cover sidewalls of the second to fifth semiconductor chips 200, 300, 400 and 500 on each of the first semiconductor chips 100.

Referring to FIG. 1 again, a first conductive connection member 180 may be formed to contact the external connection pad 140 to complete the manufacturing the semiconductor package.

As illustrated above, the thickness of the fifth semiconductor chips 500 may be reduced to be substantially the same as or slightly greater than that of each of the second to fourth semiconductor chips 200, 300 and 400, and then a plurality of fifth semiconductor chips 500 may be bonded together with the auxiliary substrate 910, and then the HCB process may be performed not by the individual unit of a chip but by the whole unit of a wafer so that the fifth semiconductor chips 500 bonded with the auxiliary substrate 910 may be bonded with the fourth semiconductor chips 400, respectively.

Accordingly, even though a total thickness (e.g., a sum of thicknesses) of the auxiliary substrate 910 and the fifth semiconductor chip 500 is greater than each thickness of the first to fourth semiconductor chips 200, 300 and 400 during the HCB process, the total thickness may not be so great/large comparing with the planar area (the footprint or the plan view area) of the wafer, and thus the auxiliary substrate 910 and the fifth semiconductor chip 500 may be partially transformed during the pressuring process so that no void may remain between the fourth and fifth semiconductor chips 400 and 500. As a result, the semiconductor package including the fifth semiconductor chip 500 and the auxiliary substrate 910 may have enhanced electrical characteristics and/or reliability.

FIGS. 12 to 19 are cross-sectional views illustrating semiconductor packages in accordance with example embodiments, which may correspond to FIG. 1.

Each of the semiconductor packages may be substantially the same as or similar to that of FIG. 1, except for some elements. Thus, repeated explanations are omitted herein. For example, elements/descriptions not repeated below may be the same as elements/descriptions disclosed above.

Referring to FIG. 12, only the ninth bonding layer 620 may be formed between the auxiliary substrate 910 and the fifth semiconductor chip 500 and the second mold 610, and the tenth bonding layer 920 may not be formed therebetween.

Referring to FIG. 13, only the tenth bonding layer 920 may be formed between the auxiliary substrate 910 and the fifth semiconductor chip 500 and the second mold 610, and the ninth bonding layer 620 may not be formed therebetween.

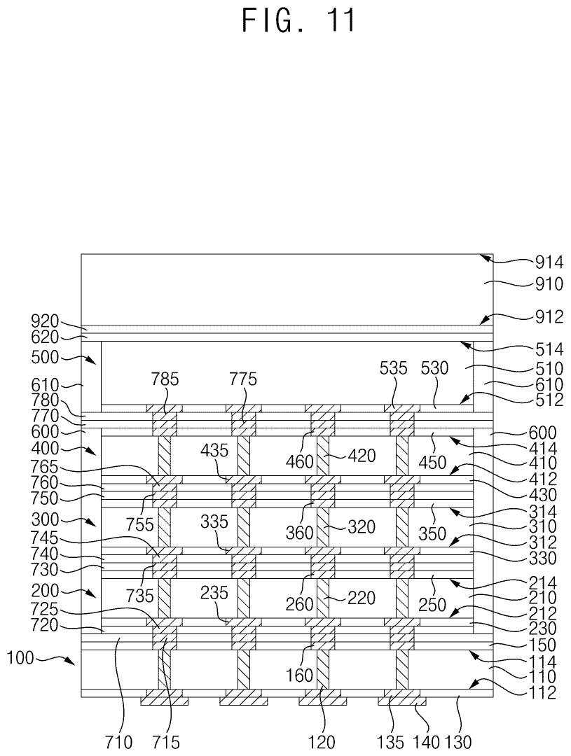

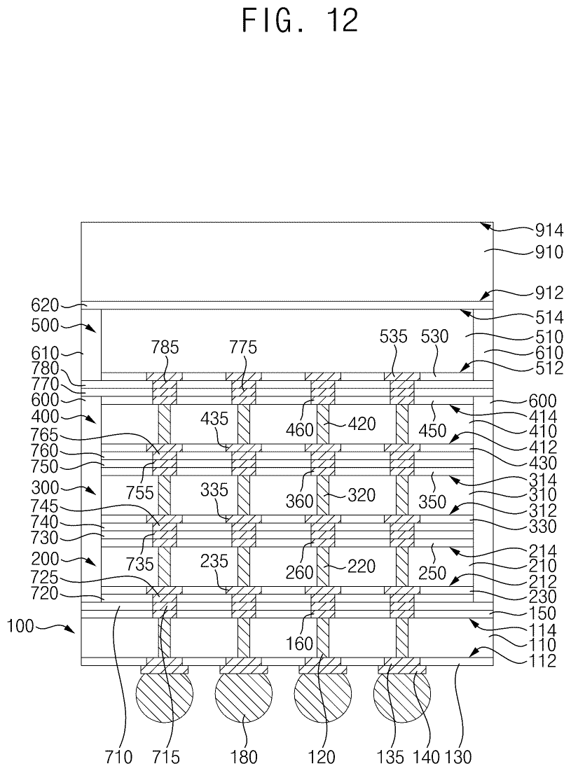

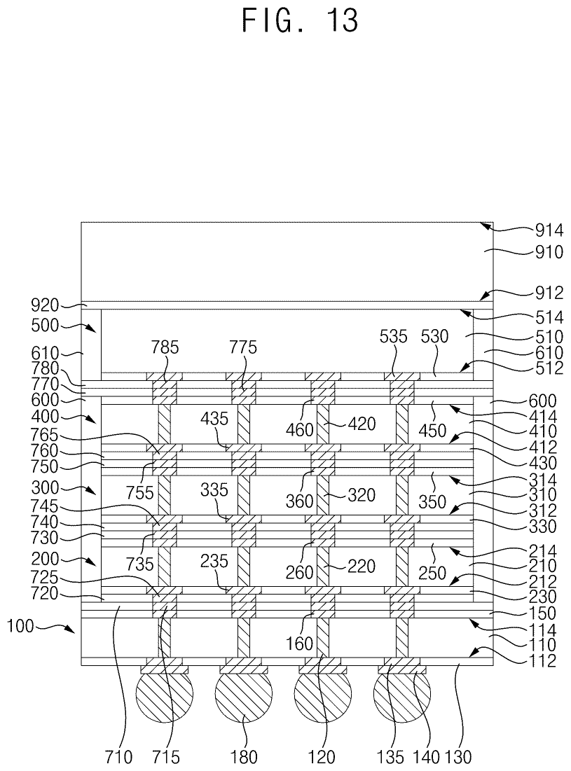

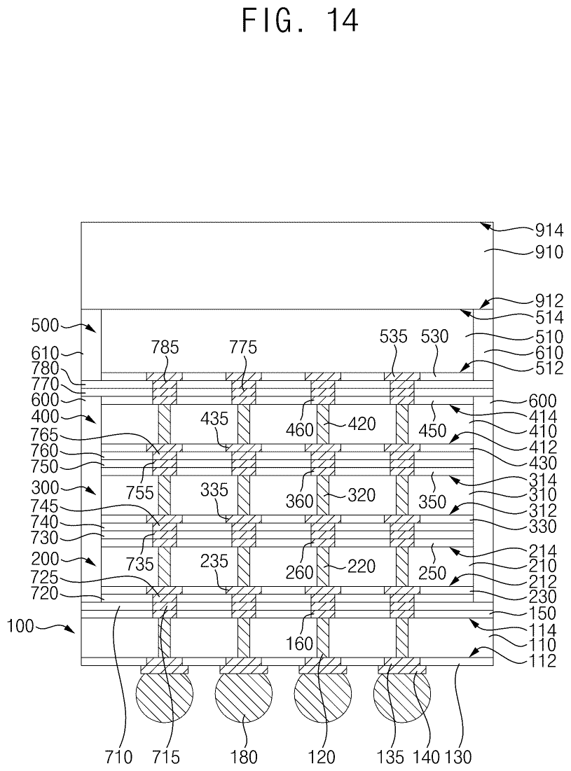

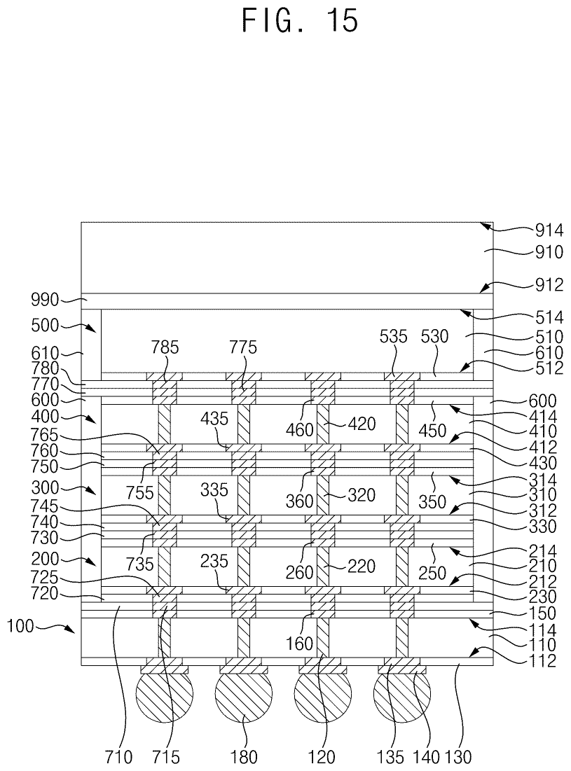

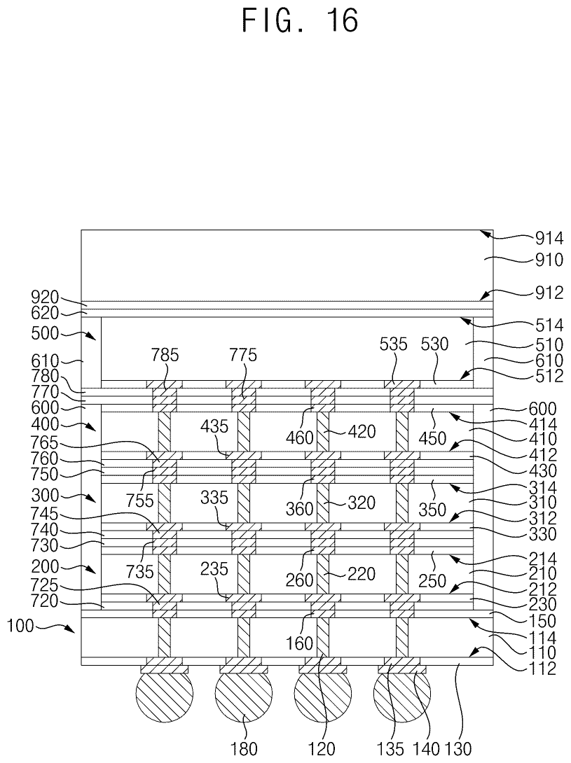

Referring to FIG. 14, neither ninth bonding layer 620 nor the tenth bonding layer 920 may be formed between the auxiliary substrate 910 and the fifth semiconductor chip 500 and the second mold 610, and thus the auxiliary substrate 910 may directly be attached to or contact the fifth semiconductor chip 500 and the second mold 610.

Referring to FIG. 15, instead of the ninth bonding layer 620 and the tenth bonding layer 920, for example, an adhesion layer 990 including, e.g., glue may be formed between the auxiliary substrate 910 and the fifth semiconductor chip 500 and the second mold 610.

Referring to FIG. 16, the first bonding layer 710 and the first conductive bonding pattern 715 may not be formed on the third insulating interlayer 150 and the first conductive pad 160 of the first semiconductor chip 100, and thus the second bonding layer 720 and the second conductive bonding pattern 725 beneath the second semiconductor chip 200 may contact the third insulating interlayer 150 and the first conductive pad 160, respectively.

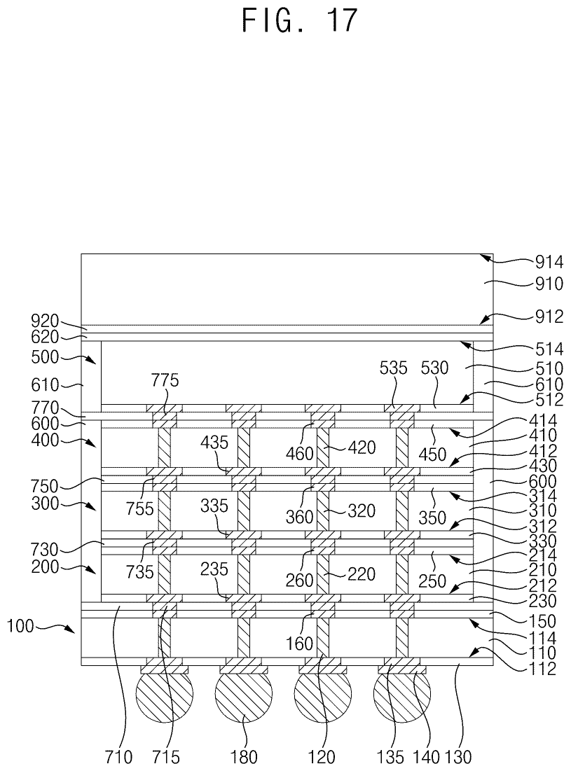

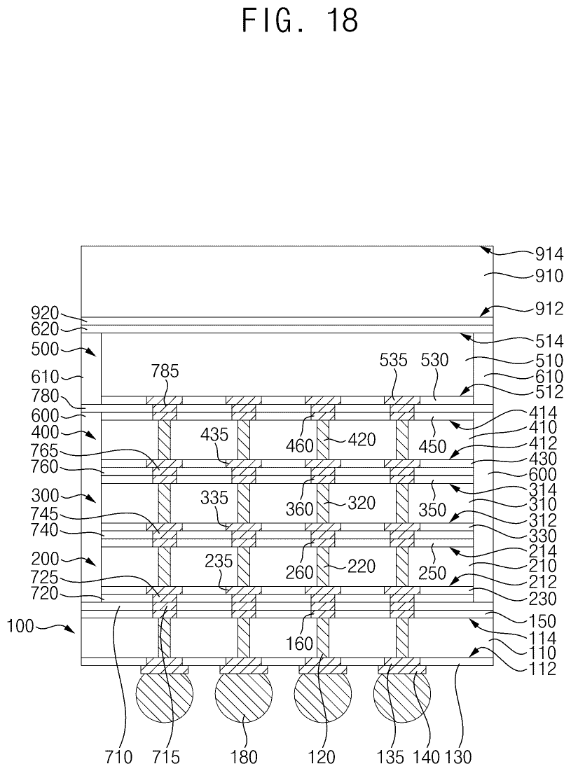

Referring to FIG. 17, the second bonding layer 720 and the second conductive bonding pattern 725, the fourth bonding layer 740 and the fourth conductive bonding pattern 745, the sixth bonding layer 760 and the sixth conductive bonding pattern 765, and the eighth bonding layer 780 and the eighth contact bonding pattern 785 may not be formed under the second to fifth semiconductor chips 200, 300, 400 and 500, respectively.

Thus, the fifth insulating interlayer 230 and the second wiring structure 235, the eighth insulating interlayer 330 and the third wiring structure 335, the eleventh insulating interlayer 430 and the fourth wiring structure 435, and the fourteenth insulating interlayer 530 and the fifth wiring structure 535 of the second to fifth semiconductor chips 200, 300, 400 and 500, respectively, may contact the first bonding layer 710 and the first conductive bonding pattern 715, the third bonding layer 730 and the third conductive bonding pattern 735, the fifth bonding layer 750 and the fifth conductive bonding pattern 755, and the seventh bonding layer 770 and the seventh conductive bonding pattern 775, respectively.

Referring to FIG. 18, the third bonding layer 730 and the third conductive bonding pattern 735, the fifth bonding layer 750 and the fifth conductive bonding pattern 755, and the seventh bonding layer 770 and the seventh conductive bonding pattern 775 may not be formed on the second to fourth semiconductor chips 200, 300 and 400, respectively.

Thus, the sixth insulating interlayer 250 and the second conductive pad 260, the ninth insulating interlayer 350 and the third conductive pad 360, and the twelfth insulating interlayer 450 and the fourth conductive pad 460 of the second to fourth semiconductor chips 200, 300 and 400, respectively, may contact the fourth bonding layer 740 and the fourth conductive bonding pattern 745, the sixth bonding layer 760 and the sixth conductive bonding pattern 765, and the eighth bonding layer 780 and the eighth conductive bonding pattern 785, respectively.

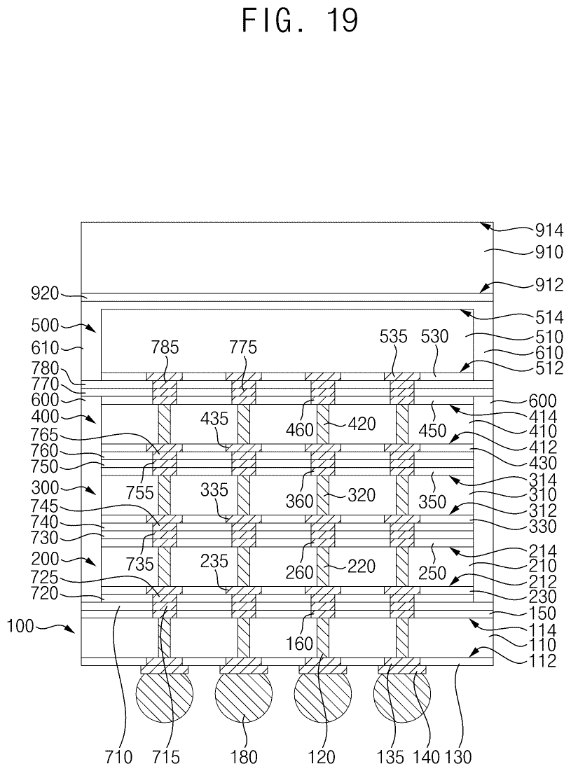

Referring to FIG. 19, the ninth bonding layer 620 may not be formed on the fifth semiconductor chip 500 and the second mold 610, and the second mold 610 may cover an upper surface of the fifth semiconductor chip 500.

Thus, the tenth bonding layer 920 may contact an upper surface of the second mold 610.

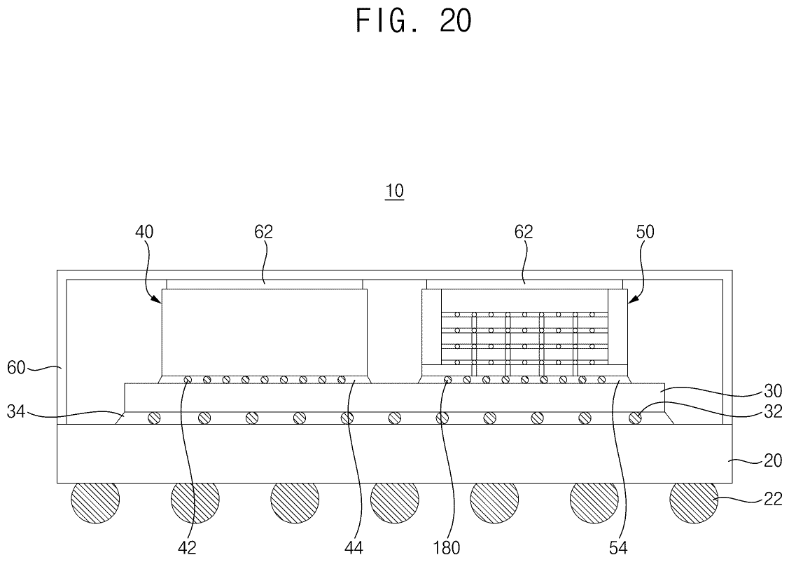

FIG. 20 is a cross-sectional view illustrating an electronic device in accordance with example embodiments.

This electronic device may include the semiconductor package shown in FIG. 1 as a second semiconductor device 50, however, the inventive concept may not be limited thereto, and may include the semiconductor packages shown in FIGS. 12 to 19, as the second semiconductor device 50.

Referring to FIG. 20, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In example embodiments, the electronic device 10 may be a memory module having a 2.5D package structure, and thus may include the interposer 30 for electrically connecting the first and second semiconductor devices 40 and 50 to each other.

In example embodiments, the first semiconductor device 40 may include or may be a logic device, and the second semiconductor device 50 may include or may be a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may be one of the semiconductor packages of FIGS. 1 and 12 to 19.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a third conductive connection member 32. In example embodiments, a planar area of the interposer 30 may be smaller than a planar area of the package substrate 20. For example, the footprint or a plan view area of the interposer 30 may be smaller than the footprint or a plan view area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be electrically connected to each other through the wirings in the interposer 30 and/or electrically connected to the package substrate 20 through the third conductive connection member 32. The third conductive connection member 32 may include or may be, e.g., a micro-bump. The silicon interposer may provide a high-density interconnection between the first and second semiconductor devices 40 and 50. For example, the silicon interposer may include multilayered conductor patterns.

The first semiconductor device 40 may be disposed on the second interposer 30. The first semiconductor device 40 may be mounted on and bonded with the interposer 30 by a TCB (Thermo-Compression Bonding) process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a fourth conductive connection member 42. For example, the fourth conductive connection member 42 may include or may be, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by a TCB process. In this case, conductive pads of the second semiconductor device 50 may be electrically connected to conductive pads of the interposer 30 by the first conductive connection member 180.

Although a single first semiconductor device 40 and a single second semiconductor device 50 are disposed on the interposer 30 in FIG. 20, the inventive concept is not limited thereto, and a plurality of first semiconductor devices 40 and/or a plurality of second conductive devices 50 may be disposed on the interposer 30.

In example embodiments, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include or be formed of a material having a relatively high fluidity to effectively fill a small/narrow space between the first and second semiconductor devices 40 and 50 and the interposer 30 and a small/narrow space between the interposer 30 and the package substrate 20. For example, each of the first to third underfill members 34, 44 and 54 may include or be formed of an adhesive containing an epoxy material.

In example embodiments, the heat slug 60 may cover the package substrate 20 to thermally contact the first and second semiconductor devices 40 and 50. For example, a heat dissipation member 62 may be disposed on an upper surface of each of the first and second semiconductor devices 40 and 50, and may include or be formed of, e.g., thermal interface material (TIM). The heat slug 60 may thermally contact the first and second semiconductor devices 40 and 50 via the heat dissipation members 62.

A conductive pad may be formed at a lower portion of the package substrate 20, and a second conductive connection member 22 may be disposed beneath the conductive pad. In example embodiments, a plurality of second conductive connection members 22 may be spaced apart from each other in the horizontal direction. The second conductive connection member 22 may be, e.g., a solder ball. The electronic device 10 may be mounted on a module board via the second conductive connection members 22 to form a memory module.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
a buffer die;
first memory dies sequentially stacked on the buffer die;
a first bonding layer structure between neighboring ones of the first memory dies, the first bonding layer structure bonding the neighboring ones of the first memory dies with each other and containing a first conductive bonding pattern structure therein;
a first mold on the buffer die, the first mold covering sidewalls of the first memory dies and the first bonding layer structure;
a second bonding layer structure on the first memory dies and the first mold, the second bonding layer structure containing a second conductive bonding pattern structure therein;
a second memory die on the second bonding layer structure;
a second mold on the second bonding layer structure, the second mold covering a sidewall of the second memory die; and
an auxiliary substrate on the second memory die and the second mold.

2. The semiconductor package according to claim 1, further comprising;
a plurality of first bonding layer structures respectively interposed between neighboring first memory dies; and
a first conductive bonding pattern structure disposed in each of the plurality of first bonding layer structurers,
wherein each of the first memory dies includes:
a first substrate; and
a through electrode extending through the first substrate, and
wherein the through electrode is electrically connected to the first conductive bonding pattern structure contained in the first bonding layer structure.

3. The semiconductor package according to claim 2, wherein the second memory die includes a second substrate, and
wherein no through electrode is disposed in the second substrate.

4. The semiconductor package according to claim 1, further comprising a third bonding layer structure between the auxiliary substrate and the second memory die and the second mold, the third bonding layer structure containing no conductive bonding pattern structure therein.

5. The semiconductor package according to claim 4, wherein the third bonding layer structure includes silicon oxide.

6. The semiconductor package according to claim 1, wherein the auxiliary substrate includes silicon, and
wherein the second memory die and the second mold contact the auxiliary substrate.

7. The semiconductor package according to claim 1, further comprising a third bonding layer structure between the buffer die and a lowermost one of the first memory dies, the third bonding layer structure bonding the buffer die and the lowermost one of the first memory dies with each other and containing a third conductive bonding pattern structure therein.

8. The semiconductor package according to claim 1, wherein the first bonding layer structure includes:
a first bonding layer including silicon carbonitride or silicon oxide; and
a second bonding layer contacting an upper surface of the first bonding layer, the second bonding layer including silicon carbonitride or silicon oxide.

9. The semiconductor package according to claim 8, wherein the first conductive bonding pattern structure includes:
a first conductive bonding pattern extending through the first bonding layer and including copper; and
a second conductive bonding pattern extending through the second bonding layer and including copper, the second conductive bonding pattern contacting the first conductive bonding pattern.

10. The semiconductor package according to claim 1, wherein a thickness of the second memory die in a vertical direction is not less than a thickness of each of the first memory dies in the vertical direction.

11. The semiconductor package according to claim 1, wherein each of the first and second molds includes silicon oxide or an organic insulating material.

12. A semiconductor package comprising:
a buffer die;
a first bonding layer structure on the buffer die, the first bonding layer structure having a footprint substantially the same as the footprint of the buffer die and containing a first conductive bonding pattern structure therein;
first memory dies sequentially stacked on the first bonding layer structure, each of the first memory dies having a footprint smaller than the footprint of the buffer die;
a second bonding layer structure between neighboring ones of the first memory dies, the second bonding layer structure bonding the neighboring ones of the first memory dies with each other, having a footprint substantially the same as the footprint of each of the first memory dies, and containing a second conductive bonding pattern structure therein;
a third bonding layer structure on an uppermost one of the first memory dies, the third bonding layer structure having a footprint substantially the same as the footprint of the buffer die and containing a third conductive bonding pattern structure therein;
a second memory die on the third bonding layer structure, the second memory die having a footprint substantially the same as the footprint of each of the first memory dies; and
an auxiliary substrate on the second memory die, the auxiliary substrate having a footprint substantially the same as the footprint of the buffer die.

13. The semiconductor package according to claim 12, further comprising:
a first mold on the first bonding layer structure, the first mold covering sidewalls of the first memory dies and the second bonding layer structure; and
a second mold on the third bonding layer structure, the second mold covering a sidewall of the second memory die.

14. The semiconductor package according to claim 13, wherein each of the first and second molds includes silicon oxide or an organic insulating material, and
wherein each of the first to third bonding layer structures includes silicon carbonitride.

15. The semiconductor package according to claim 12, further comprising;
a plurality of second bonding layer structures respectively interposed between neighboring first memory dies; and
a second conductive bonding pattern structure disposed in each of the plurality of second bonding layer structurers,
wherein each of the first memory dies includes:
a first substrate; and
a through electrode extending through the first substrate, and
wherein the through electrode is electrically connected to the second conductive bonding pattern structure contained in a corresponding second bonding layer structure.

16. The semiconductor package according to claim 15, wherein the second memory die includes a second substrate, and
wherein the second substrate does not include a through electrode therein.

17. The semiconductor package according to claim 12, further comprising a fourth bonding layer structure between the second memory die and the auxiliary substrate, the fourth bonding layer structure containing no conductive pattern structure therein.

18. The semiconductor package according to claim 17, wherein the fourth bonding layer structure includes silicon oxide.

19. A semiconductor package comprising:
a buffer die;
a first bonding layer structure on the buffer die, the first bonding layer structure containing a first conductive bonding pattern structure therein;
first memory dies sequentially stacked on the first bonding layer structure;
a second bonding layer structure between neighboring ones of the first memory dies, the second bonding layer structure bonding the neighboring ones of the first memory dies with each other and containing a second conductive bonding pattern structure therein;
a first mold on the first bonding layer structure, the first mold covering sidewalls of the first memory dies and the second bonding layer structure;
a third bonding layer structure on the first memory dies and the first mold, the third bonding layer structure containing a third conductive bonding pattern structure therein;
a second memory die on the third bonding layer structure;
a second mold on the third bonding layer structure, the second mold covering a sidewall of the second memory die;
a fourth bonding layer structure on the second memory die and the second mold;
an auxiliary substrate on the fourth bonding layer structure; and
a conductive connection member electrically connected to the buffer die.

20. The semiconductor package according to claim 19, further comprising: a plurality of second bonding layer structures respectively interposed between neighboring first memory dies; and
a second conductive bonding pattern structure disposed in each of the plurality of second bonding layer structurers,
wherein:
each of the first memory dies includes:
a first substrate; and
a through electrode extending through the first substrate,
each of the plurality of second bonding layer structures includes:
a first bonding layer; and
a second bonding layer contacting an upper surface of the first bonding layer,
the second conductive bonding pattern structure includes:
a first conductive bonding pattern extending through the first bonding layer; and
a second conductive bonding pattern extending through the second bonding layer and contacting the first conductive bonding pattern, and
the through electrode is electrically connected to corresponding first and second conductive bonding patterns.
